(19) United States
(12) Patent Application Publication
(10) Pub. No.: US 2026/0239846 A1
(43) Pub. Date: Aug. 13, 2026

(54) DISPLAY DEVICE

(71) Applicant: Samsung Display Co., Ltd., Yongin-Si (KR)

(72) Inventors: Han Bum KWON, Yongin-si (KR); Eun Byul KIM, Yongin-si (KR); Young Min AHN, Yongin-si (KR); Kyung Bin CHOI, Yongin-si (KR)

(21) Appl. No.: 19/325,509

(22) Filed: Sep. 11, 2025

(30) Foreign Application Priority Data
Feb. 10, 2025 (KR) 10-2025-0016662

(51) Int. Cl. H10K 59/131

(52) U.S. Cl. CPC H10K 59/1315

(57) ABSTRACT

A display device is provided. The display device comprises a display panel connected to a driver circuit. The display panel includes a first substrate; a pad located on the first substrate; and a residual capping pattern on the pad. The driver circuit includes: a second substrate; and a terminal located on the second substrate and directly connected to the pad of the display panel. The residual capping pattern is located between the pad of the display panel and the terminal of the driver circuit.

### CROSS-REFERENCE TO RELATED APPLICATION(S)

This application claims priority from Korean Patent Application No. 10-2025-0016662 filed on February 10, 2025 in the Korean Intellectual Property Office, and all the benefits accruing therefrom under 35 U.S.C. 119, the contents of which in its entirety are herein incorporated by reference.

### BACKGROUND

### 1. Field of the Disclosure

The present disclosure relates to a display device, and more particularly, to a display device with reduced contact resistance between a display panel and a circuit board.

### 2. Description of Related Art

An organic light-emitting diode display, unlike a liquid-crystal display, is self-luminous. Accordingly, an organic light-emitting diode display does not require a separate light source and thus it can be made lighter and thinner. In addition, an organic light-emitting diode display has high-quality characteristics such as low power consumption, high luminance and fast response speed, and thus is attracting attention as the next generation display.

### SUMMARY

Aspects of the present disclosure provide a display device in which the contact resistance between a display panel and a driver circuit can be reduced.

advantages of the present disclosure will be apparent to those skilled in the art from the following descriptions.

According to an aspect of the present disclosure, a display device comprises a display panel and a driver circuit connected to the display panel. The display panel includes a first substrate; a pad located on the first substrate; and a residual capping pattern located on the pad. The driver circuit comprises: a second substrate; and a terminal located on the second substrate and directly connected to the pad of the display panel, wherein the residual capping pattern is located between the pad of the display panel and the terminal of the driver circuit.

In an embodiment, the terminal of the driver circuit comprises a first terminal electrode located on the second substrate, and a second terminal electrode located on the first terminal electrode, and wherein a hardness of the first terminal electrode is different from a hardness of the second terminal electrode.

In an embodiment, a hardness of the second terminal electrode is greater than a hardness of the first terminal electrode.

In an embodiment, the terminal of the driver circuit comprises: a first terminal electrode located on the second substrate, and a second terminal electrode located on the first terminal electrode, and wherein the second terminal electrode is in direct contact with the pad of the display panel.

In an embodiment, The display device of claim 4, wherein the residual capping pattern comprises a first residual capping pattern located on the pad, and a second residual capping pattern located on the first residual capping pattern, wherein the first residual capping pattern is not in direct contact with the second terminal electrode of the driver circuit, and wherein the second residual capping pattern is in direct contact with the second terminal electrode of the driver circuit.

In an embodiment, the residual capping pattern comprises a first residual capping pattern located on the pad, and a second residual capping pattern located on the first residual capping pattern, wherein the first residual capping pattern is in direct contact with the second terminal electrode of the driver circuit, and wherein the second residual capping pattern is not in direct contact with the second terminal electrode of the driver circuit.

In an embodiment, the residual capping pattern comprises a first residual capping pattern located on the pad, and a second residual capping pattern located on the first residual capping pattern, and wherein the first residual capping pattern and the second residual capping pattern are in direct contact with the second terminal electrode of the driver circuit.

In an embodiment, the terminal of the driver circuit comprises: a first terminal electrode located on the second substrate, and a second terminal electrode located on the first terminal electrode, and wherein the second terminal electrode comprises a solder metal.

In an embodiment, the display device further comprises a non-conductive film between the display panel and the driver circuit, wherein a melting point of the second terminal electrode is different from a melting point of the non-conductive film.

In an embodiment, the melting point of the second terminal electrode is lower than the melting point of the non-conductive film.

In an embodiment, a surface of the second terminal electrode which faces the pad has an irregular uneven shape.

In an embodiment, the display device further comprises a capping member located on the pad, and wherein the terminal of the driver circuit is in direct contact with the pad through the capping member.

In an embodiment, the residual capping pattern comprises a first residual capping pattern located on the pad, and a second residual capping pattern located on the first residual capping pattern, wherein the first residual capping pattern is not in direct contact with the terminal of the driver circuit, and wherein the second residual capping pattern is in direct contact with the terminal of the driver circuit.

In an embodiment, the residual capping pattern comprises a first residual capping pattern located on the pad, and a second residual capping pattern located on the first residual capping pattern, wherein the first residual capping pattern is in direct contact with the terminal of the driver circuit, and wherein the second residual capping pattern is not in direct contact with the terminal of the driver circuit.

In an embodiment, the residual capping pattern comprises a first residual capping pattern located on the pad and a second residual capping pattern located on the first residual capping pattern, and wherein the first residual capping pattern and the second residual capping pattern are in direct contact with the terminal of the driver circuit.

In an embodiment, the terminal comprises a solder metal.

In an embodiment, the display device further comprises a non-conductive film between the display panel and the driver circuit, wherein a melting point of the terminal is different from a melting point of the non-conductive film.

In an embodiment, the melting point of the terminal is lower than the melting point of the non-conductive film.

In an embodiment, a surface of the terminal which faces the pad has an irregular uneven shape.

According to an aspect of the present disclosure, an electronic device including a display device comprises a display panel and a driver circuit connected to the display panel. The display panel comprises a first substrate; a pad located on the first substrate; and a residual capping pattern on the pad. The driver circuit comprises: a second substrate; and a terminal located on the second substrate and directly connected to the pad of the display panel. The residual capping pattern is located between the pad of the display panel and the terminal of the driver circuit.

According to an embodiment of the present disclosure, the contact resistance between a display panel and a driver circuit of a display device can be reduced, and thus the reliability of the display device can be improved.

For example, the terminal of the driver circuit may include a terminal electrode including a high-hardness, heat-melting metal, so that the terminal electrode of the driver circuit may penetrate and destroy a capping member positioned on a pad of the display panel, thereby improving the physical contact between the terminal electrode and the pad. As the terminal electrode of the driver circuit is melted and solidified, the contact area between the pad of the display panel and the terminal of the driver circuit can be increased. Accordingly, the contact resistance between the terminal of the driver circuit and the pad of the display panel can be reduced.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view showing a display device according to an embodiment of the present disclosure.

FIG. 2 is a plan view of the display device of FIG. 1 without a first circuit board and a second circuit board.

FIG. 3 is an enlarged view of portion A1 of FIG. 2.

FIG. 4 is a cross-sectional view taken along line X1 - X1' of FIG. 3.

FIG. 5 is a cross-sectional view of a display device according to an embodiment of the present disclosure when a display panel and a driver circuit are attached to each other, taken along line X1 – X1' of FIG. 3.

FIG. 6 is an enlarged view of portion A3 of FIG. 5.

FIGS. 7 and 8 are cross-sectional views of a display device for illustrating a process of attaching a display panel to a driver circuit according to an embodiment.

FIG. 9 is an enlarged view of portion A5 of FIG. 8.

FIG. 10 is a cross-sectional view of a display device according to another embodiment of the present disclosure, taken along line X1 – X1' of FIG. 3.

FIG. 11 is a block diagram of an electronic device according to an embodiment of the present disclosure.

FIG. 12 is a view showing electronic devices according to a variety of embodiments of the present disclosure.

### DETAILED DESCRIPTION OF THE EMBODIMENTS

The present inventive concept will now be described more fully hereinafter with reference to the accompanying drawings, in which embodiments are shown. This inventive concept may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being "on" another layer or substrate, it can be directly on the other layer or substrate, or intervening layers may be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined with each other, in part or in whole, and technically various interlocking and driving are possible. Each embodiment may be implemented independently of each other or may be implemented together in an association.

Hereinafter, embodiments of the present disclosure will be described in detail with reference to the accompanying drawings.

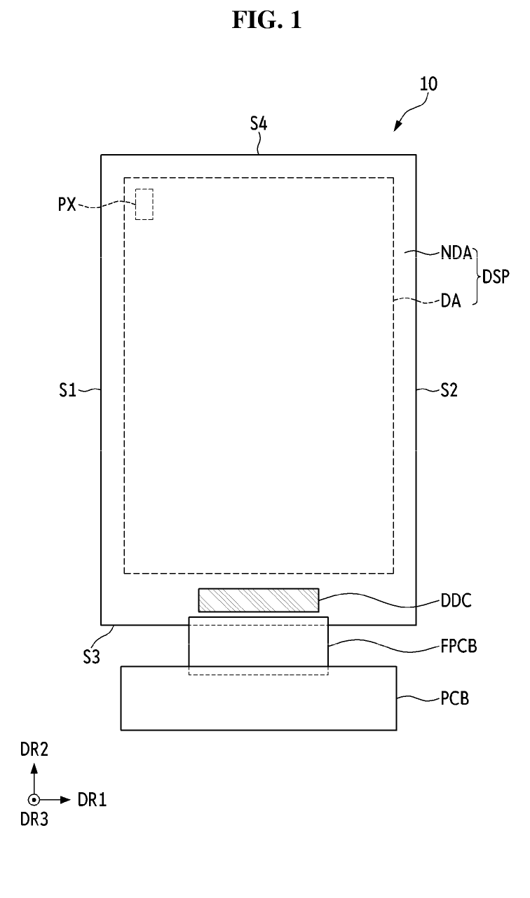

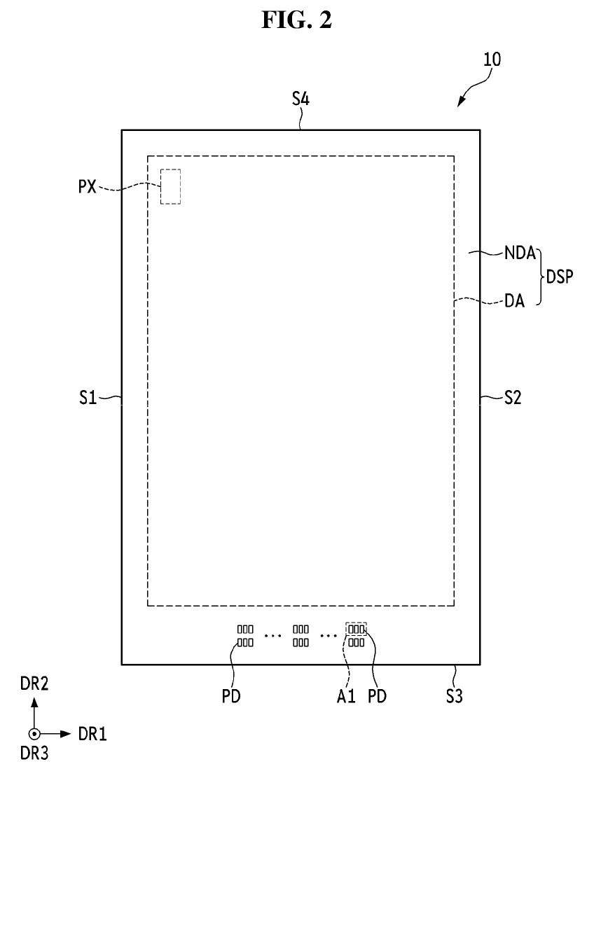

FIG. 1 is a plan view showing a display device according to an embodiment of the present disclosure. FIG. 2 is a plan view of the display device of FIG. 1 from which a first circuit board and a second circuit board have been removed.

Referring to FIG. 1, a display device 10 displays moving images or still images and may be used as a display screen of a variety of electronic devices.

The display device 10 may be a light-emitting display device such as an organic light-emitting display device including organic light-emitting diodes, a quantum-dot light-emitting display device including quantum-dot light-emitting layer, and an ultra-small light-emitting display device including ultra-small light-emitting diodes such as micro or nano light-emitting diodes (micro LEDs or nano LEDs). It should be understood, however, that the present disclosure is not limited thereto. For example, the display device 10 may be other types of display devices than light-emitting display devices. In the following descriptions, a light-emitting display device (e.g., an organic light-emitting display device) is disclosed as the display device 10.

As used herein, a first direction DR1 may be parallel to the shorter sides of the display device 10, for example, the horizontal direction of the display device 10 referencing FIG. 1. A second direction DR2 may be parallel to the longer sides of the display device 10, for example, the vertical direction of the display device 10 referencing FIG. 1. A third direction DR3 may refer to the thickness direction of the display device 10. The display device 10 may have a rectangular shape when viewed from the top.

The display device 10 may include a display panel DSP, a first circuit board FPCB, a second circuit board PCB, and a driver circuit DDC (e.g., a data driver circuit).

The display panel DSP may be a rigid display panel, or a flexible display panel that can be transformed, i.e., at least partially folded, bent or rolled. The display panel DSP may be provided to the display device 10 without being bent or with being partially bent, for example in a substantially flat form.

The display panel DSP 200 may include a display area DA and a non-display area NDA.

A plurality of pixels PX may be arranged in the display area DA. The pixels PX can display images. In addition, a plurality of gate lines and a plurality of emission lines connected to the pixels PX may be arranged in the display area DA. The display area DA may have a variety of shapes depending on embodiments. For example, the display area DA may have a rectangular shape, a non-rectangular polygonal shape, a circular shape, an elliptical shape, an irregular shape, or other shapes. According to an embodiment of the present disclosure, the display area DA may have a shape that is similar to the shape of the display panel DSP.

The non-display area NDA may be located around the display area DA. According to the embodiment of the present disclosure, the non-display area NDA may surround the display area DA. A gate driver and an emission driver for driving the pixels PX may be arranged in the non-display area NDA of the display panel DSP. The gate driver may be connected to the gate lines, and the emission driver may be connected to the emission lines. The gate signals from the gate driver may be provided to the pixels PX through the gate lines, and emission signals from the emission driver may be provided to the pixels PX through the emission lines.

A first side S1 and a second side S2 of the display panel DSP face each other in the first direction DR1, and a third side S3 and a fourth side S4 of the display panel DSP may face each other in the second direction DR2. The first circuit board FPCB described above may overlap with the third side S3. The first side S1 or the second side S2 may be longer than the third side S3 or the fourth side S4. It should be understood, however, that the embodiments of the present disclosure are not limited thereto. The lengths of the first side S1, the second side S2, the third side S3 and the fourth side S4 may be changed in a variety of ways.

The driver circuit DDC may be connected to the display panel DSP. For example, the driver circuit DDC may be electrically connected to the non-display area NDA of the display panel DSP. The driver circuit DDC may include, for example, an integrated circuit.

The first circuit board FPCB may be connected to the display panel DSP and the second circuit board PCB. For example, one side of the first circuit board FPCB may be electrically connected to the non-display area NDA of the display panel DSP, and the other side of the first circuit board FPCB may be electrically connected to the second circuit board PCB. The first circuit board FPCB may be, but is not limited to, a flexible film such as a flexible printed circuit board and a printed circuit board. For example, the first circuit board FPCB may be a flexible printed circuit board.

The second circuit board PCB may be electrically connected to the display panel DSP through the first circuit board FPCB and may send/receive signals to/from the driver circuit DDC. The second circuit board PCB may provide image data, a control signal, supply voltage, etc. to the display panel DSP or the first circuit board FPCB. Active components and passive components may be arranged on the second circuit board PCB. For example, a timing controller and a power supply unit may be arranged on the second circuit board PCB. The second circuit board PCB may be, but is not limited to, a flexible printed circuit board or a printed circuit board. For example, the second circuit board PCB may be a rigid printed circuit board.

The power supply unit may apply supply voltages to the pixels PX, the gate driver, the emission driver, and the data driver circuit DDC. The timing controller may control the operations of the gate driver, the emission driver ED, and the driver circuit DDC.

A gate timing control signal, an emission timing control signal, a gate clock signal, an emission clock signal, a gate start signal, an emission start signal, a high-level voltage and a low-level voltage from the timing controller arranged on the second circuit board PCB may be provided to the first gate driver and the emission driver through the first circuit board FPCB. For example, the gate timing control signal, the gate clock signal, the gate start signal, the high-level voltage and the low-level voltage may be provided to the gate driver, and the emission timing control signal, the emission clock signal, the emission start signal, the high-level voltage and the low-level voltage may be provided to the emission driver. In addition, power signals from the power supply unit placed on the second circuit board PCB may be provided to the gate driver, the emission driver and the pixels PX through the first circuit board FPCB. The power signals may include, for example, a supply voltage, a common voltage, an initialization voltage, and a bias voltage.

Referring to FIG. 2, a plurality of pads PD may be arranged in the non-display area NDA of the display panel DSP. For example, a plurality of pads PD may be arranged close to one edge (e.g., the third side S3) of the display panel DSP. The plurality of pads PD may be arranged along the third side S3. For example, the plurality of pads PD may be arranged in the first direction DR1.

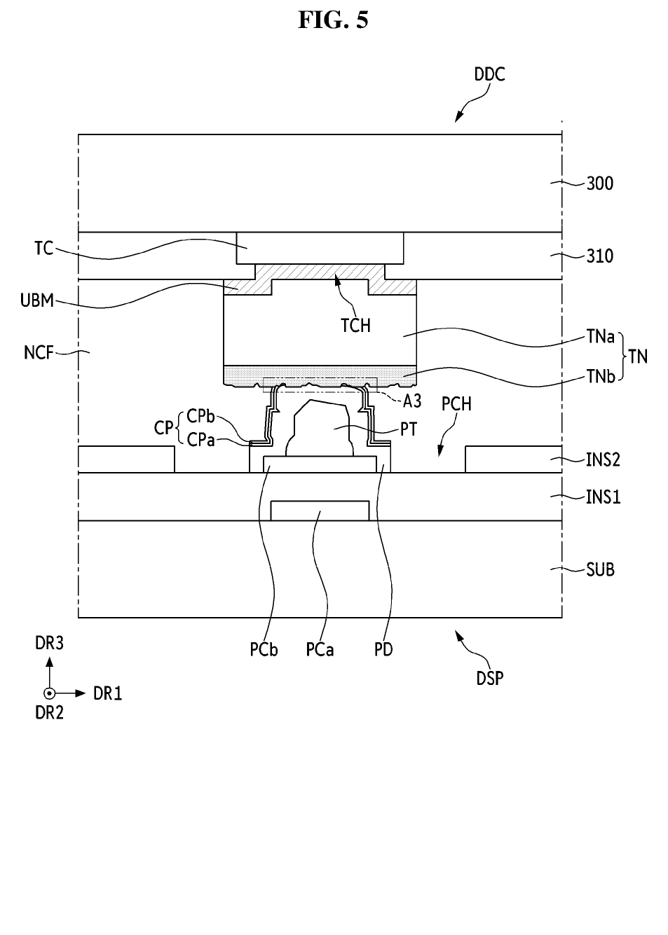

The plurality of pads PD of the display panel DSP may be connected to a plurality of terminals TN (see FIG. 5) or bumps of the driver circuit DDC. Among the plurality of pads PD of FIG. 2, pads closer to the third side S3 (e.g., input pads) may transmit signals from the first circuit board FPCB and the second circuit board PCB to the driver circuit DDC. Among the plurality of pads PD of FIG. 2, pads closer to the display area DA (e.g., output pads) may transmit signals from the driver circuit DDC to the pixels PX of the display area DA.

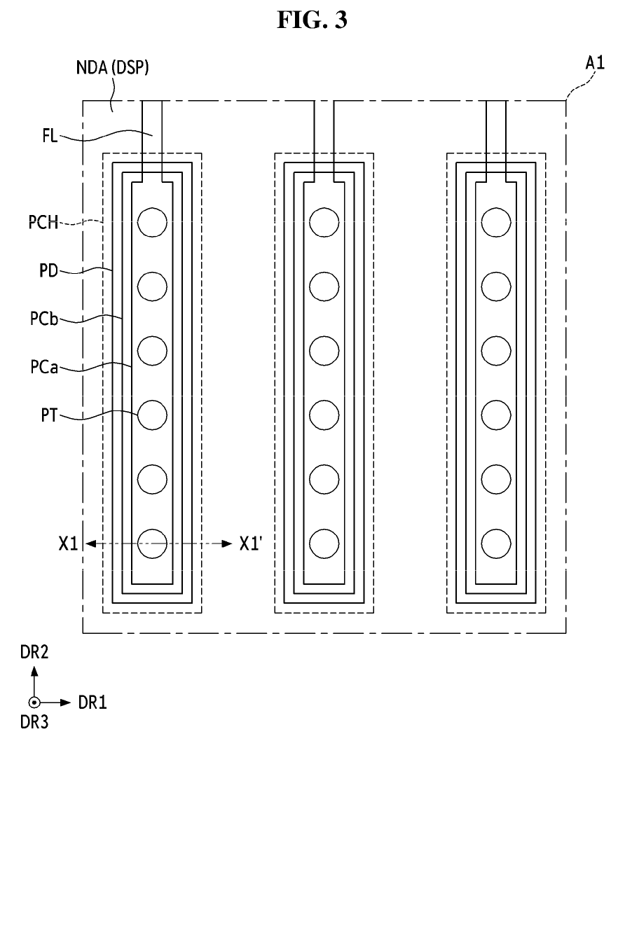

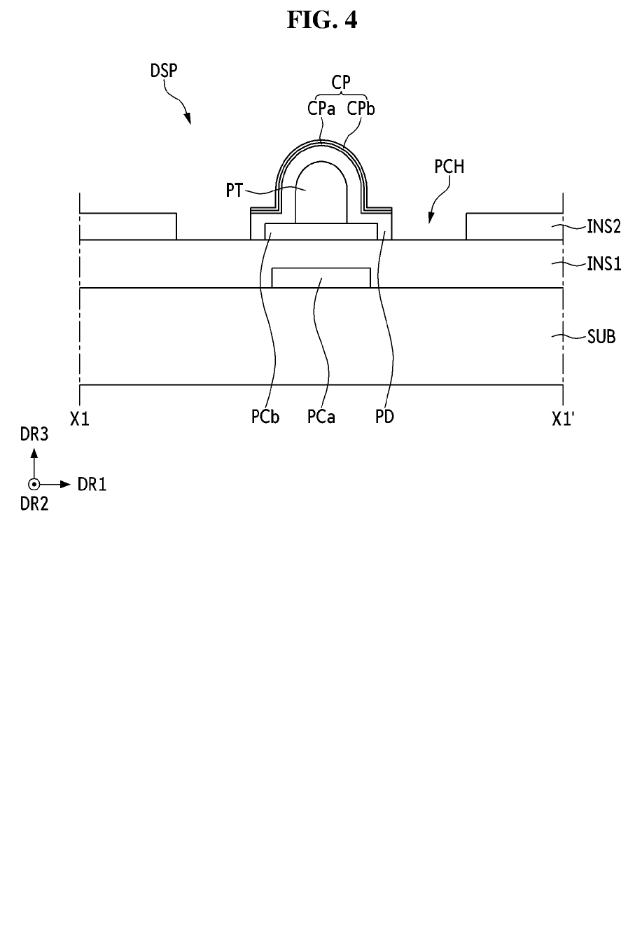

FIG. 3 is an enlarged view of portion A1 of FIG. 2. FIG. 4 is a cross-sectional view taken along line X1 - X1' of FIG. 3.

Referring to FIGS. 3 and 4, a first pad connection electrode PCa may be placed on the substrate SUB of the display panel DSP. The first pad connection electrode PCa may include a conductive material including molybdenum (Mo), aluminum (Al), copper (Cu), titanium (Ti), etc., and may be made up of multiple layers or a single layer including the above-described materials. A first insulating layer INS1 may be located on the first pad connection electrode PCa. The substrate SUB may herein also be referred to as a “first substrate.”

A second pad connection electrode PCb may be located on the first insulating layer INS1 such that it overlaps with the first pad connection electrode PCa. The second pad connection electrode PCb may be connected to the first pad connection electrode PCa. To this end, a portion of the second pad connection electrode PCb extending toward the display area DA may be connected to a fan-out line FL through a contact hole in the first insulating layer INS1. As described above, the fan-out line FL may be formed integrally with the first pad connection electrode PCa. The second pad connection electrode PCb may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and/or copper (Cu), and may be made up of a single layer or multiple layers of the above-listed materials.

A second insulating layer INS2 may be placed on the first insulating layer INS1. The second insulating layer INS2 may be in contact with (or in direct contact with) the first insulating layer INS1. The second insulating layer INS2 may have a pad contact hole PCH.

Protruding patterns PT may be arranged on the second pad connection electrode PCb. For example, the protruding patterns PT may be arranged on the second pad connection electrode PCb in the pad contact hole PCH. The protruding patterns PT may be in contact (or direct contact) with the second pad connection electrode PCb. The protruding patterns PT may have a hemispherical shape. For example, in the plan view of FIG. 3, the protruding patterns PT may have a circuit shape. In the cross-sectional view of FIG. 4, the protruding patterns PT may have a semicircular shape. For example, from a cross-sectional perspective, the protruding patterns PT may have a parabolic or lens shape that protrudes convex toward the driver circuit DDC. It should be understood, however, that the embodiments of the present disclosure are not limited thereto. The protruding patterns PT1 may have a variety of shapes such as a circle and a triangle. The protruding patterns PT may include a polymer-based material. The polymer-based material may include an acrylic resin, an epoxy resin, polyimide, polyethylene, etc. In some embodiments, the protruding patterns PT may be an inelastic polymer material. Alternatively, in some embodiments, the protruding patterns PT may be an elastic polymer material.

A pad PD may be arranged on the first insulating layer INS1, the protruding patterns PT and the second pad connection electrode PCb. The pad PD may be in contact with the first insulating layer INS1, the protruding patterns PT and the second pad connection electrode PCb. The pad PD may be connected to the fan-out line FL. For example, the pad PD may be connected to the fan-out line FL via the second pad connection electrode PCb and the first pad connection electrode PCa. The fan-out line FL may be connected to a data line, for example. The pad PD may include a conductive material including molybdenum (Mo), aluminum (Al), copper (Cu), titanium (Ti), etc.

As a plurality of protruding patterns PT is arranged along the longitudinal direction of the pad PD (e.g., the second direction DR2), the pad PD on the plurality of protruding patterns PT may have concavities and convexities. For example, the pad PD may have convexities protruding in the third direction DR3 and concavities recessed in the reverse direction of the third direction DR3 (hereinafter, the “third reverse direction”). Specifically, the pad PD may protrude in the third direction DR3 on the protruding pattern PT and may be recessed in the third reverse direction between adjacent protruding patterns PT. The pad PD protruding in the third direction DR3 may be in contact with a terminal TN of the driver circuit DDC. By such contact, the pad PD of the display panel DSP may be electrically connected with the terminal TN of the driver circuit DDC to be described later (see FIG. 5).

A capping member CP may be located on the pad PD and may overlap the pad PD. The capping member CP may be disposed on the pad PD in the form of a thin film in order to prevent the pad PD from being oxidized. The capping member CP may include a first capping member CPa and a second capping member CPb. The first capping member CPa may be placed on the pad PD. The first capping member CPa may be a material having conductivity so as to be electrically connected to the pad PD. In some embodiments, the first capping member CPa may be a conductive material, such as titanium (Ti). The second capping member CPb may be placed on the first capping member CPa. The second capping member CPb may be an oxide of the first capping member CPa. In some embodiments, the second capping member CPb may be a metal oxide, such as titanium oxide.

FIG. 5 is a cross-sectional view of a display device according to an embodiment of the present disclosure when a display panel and a driver circuit are bonded together, taken along line X1 – X1' of FIG. 3.

The following descriptions will focus on differences, and the redundant descriptions will be omitted.

Referring to FIG. 5, the driver circuit DDC may be located on the pad PD of the display panel DSP.

The driver circuit DDC may include a substrate 300, a first terminal connection electrode TC, an insulating layer 310, a second terminal connection electrode UBM, and a terminal TN. The substrate 300 may herein referred to as a “second substrate.”

A plurality of transistors (or chips) may be arranged on the substrate 300. The substrate 300 may include a wafer, and the like.

The first terminal connection electrode TC may be located on the substrate 300. The terminal connection electrode TC may be connected to a transistor on the substrate 300.

The insulating layer 310 may be located on the terminal connection electrode TC. The insulating layer 310 may have a terminal contact hole TCH that extends to the terminal connection electrode TC.

The second terminal connection electrode UBM may be located on the first terminal connection electrode TC and the insulating layer 310. The second terminal connection electrode UBM may be in contact (or direct contact) with the first terminal connection electrode TC and the insulating layer 310. The second terminal connection electrode UBM may be connected to the first terminal connection electrode TC through the terminal contact hole TCH of the insulating layer 310. The second terminal connection electrode UBM may electrically connect the first terminal connection electrode TC with the terminal TN. The second terminal connection electrode UBM may include a conductive material including copper (Cu), nickel (Ni), gold (Au), chromium (Cr), or a combination thereof.

The terminal TN may be placed on the second terminal connection electrode UBM. The terminal TN may be connected to the first terminal connection electrode TC via the second terminal connection electrode UBM. The terminal TN may be made up of multiple films. For example, the terminal may include a first terminal electrode TNa and a second terminal electrode TNb. The first terminal electrode TNa may be located on the second terminal connection electrode UBM. The first terminal electrode TNa may be connected to the terminal connection electrode TC via the second terminal connection electrode UBM. The first terminal electrode TNa may be made of a conductive material including gold (Au), etc. The second terminal electrode TNb may be located on the first terminal electrode TNa. The second terminal electrode TNb and the first terminal electrode TNa may be in contact (or direct contact) with each other. The second terminal electrode TNb may be in direct contact with the pad PD of the display panel DSP. The terminal TN of the driver circuit DDC may be electrically connected to the pad PD of the display panel DSP by the second terminal electrode TNb. The second terminal electrode TNb may be made of a high-hardness, heat-melting metal material (solder metal). In some embodiments, the second terminal electrode TNb may be an alloy including tin (Sn), silver (Ag), copper (Cu), etc. The hardness of the first terminal electrode TNa may be different from the hardness of the second terminal electrode TNb. In some embodiments, the hardness of the second terminal electrode TNb may be greater than the hardness of the first terminal electrode TNa.

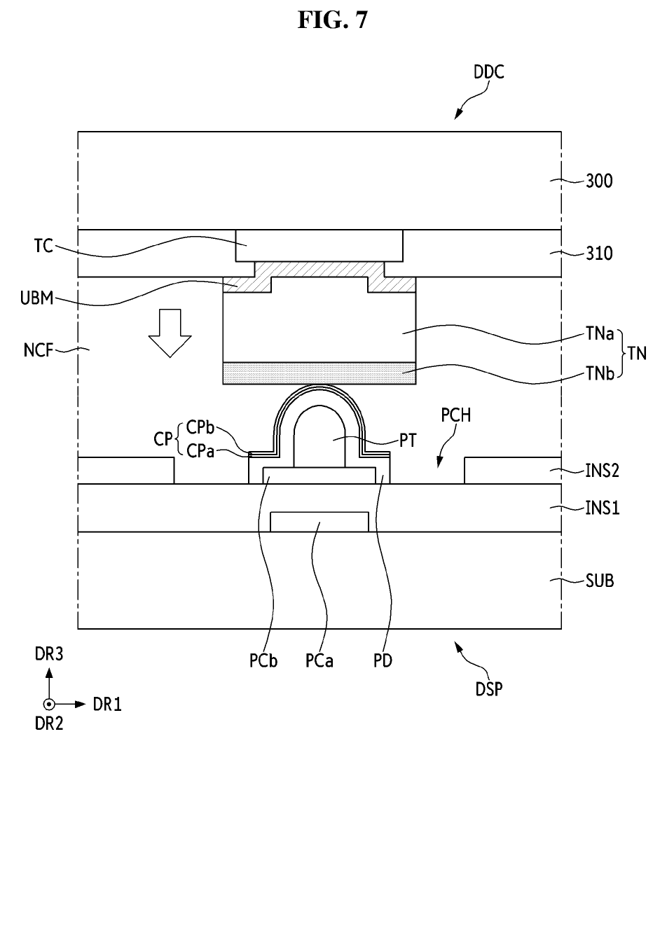

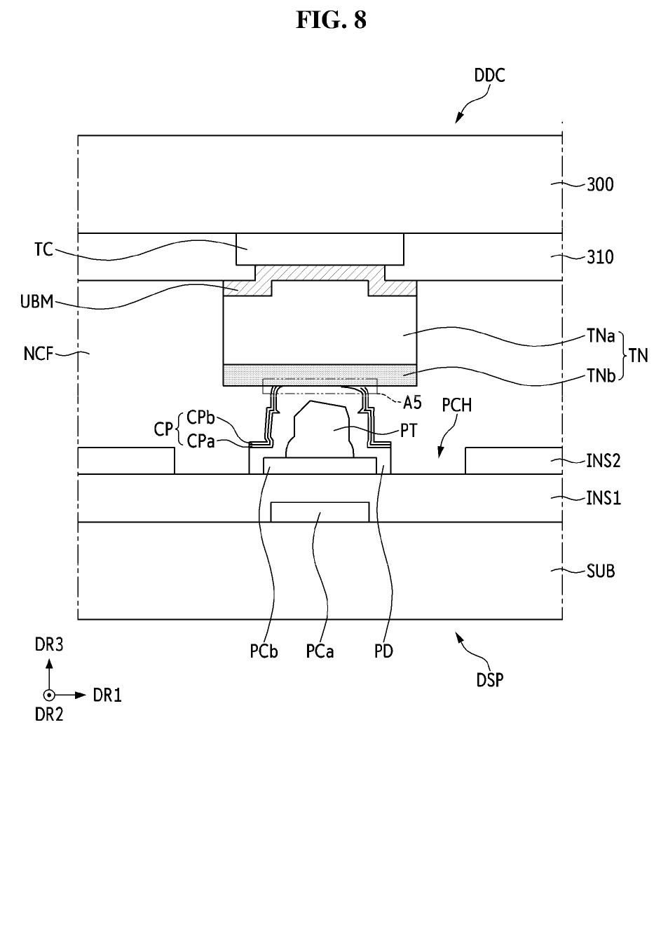

Since the second terminal electrode TNb has high hardness, during the process of bonding the display panel DSP and the driver circuit DDC described later, the high hardness second terminal electrode TNb penetrates and damages the capping member CP located on the pad PD of the display panel DSP, so that direct physical contact can be made between the second terminal electrode TNb and the pad PD. The process in which the second terminal electrode TNb of the driver circuit DDC penetrates and damages the capping member CP located on the pad PD of the display panel DSP and makes contact with the pad PD will be described in detail later with reference to FIGS. 7 and 8.

A non-conductive film (NCF) may be placed between the display panel DSP and the driver circuit DDC. For example, the non-conductive film NCF may be located between the pad PD and the terminal TN. The display panel DSP and the driver circuit DDC may be attached to each other by the non-conductive film NCF. The non-conductive film NCF may be made of a material including a thermosetting resin. The melting point of the non-conductive film NCF may be different from the melting point of the second terminal electrode TNb. In some embodiments, the melting point of the second terminal electrode TNb may be lower than the melting point of the non-conductive film NCF. Therefore, in the process of attaching the display panel DSP to the driver circuit DDC with the non-conductive film NCF, the connection between the pad PD of the display panel DSP and the terminal TN of the driver circuit DDC can be made without requiring additional heat to melt the second terminal electrode TNb.

There may be a residual capping pattern RCP on the surface of the pad PD of the display panel DSP which faces the second terminal electrode TNb of the driver circuit DDC. The residual capping pattern RCP may be a remaining portion of the capping member CP that is pressed and damaged by the second terminal electrode TNb of the driver circuit DDC during the process of attaching the display panel DSP with the driver circuit DDC. A process of forming the residual capping pattern RCP will be described in detail below, with reference to FIGS. 7 and 8. The residual capping pattern RCP may include a first residual capping pattern RCP1 and a second residual capping pattern RCP2. The first residual capping pattern RCP1 may be part of the first capping member CPa. The first residual capping pattern RCP1 may be located on the pad PD. In some embodiments, the first residual capping pattern RCP1 may be in direct contact with the second terminal electrode TNb. Alternatively, in some embodiments, the first residual capping pattern RCP1 may not be in direct contact with the second terminal electrode TNb. The second residual capping pattern RCP2 may be part of the second capping member CPb. The second residual capping pattern RCP2 may be located on the first residual capping pattern RCP1. In some embodiments, the second residual capping pattern RCP2 may be in direct contact with the second terminal electrode TNb. Alternatively, in some embodiments, the second residual capping pattern RCP2 may not be in direct contact with the second terminal electrode TNb.

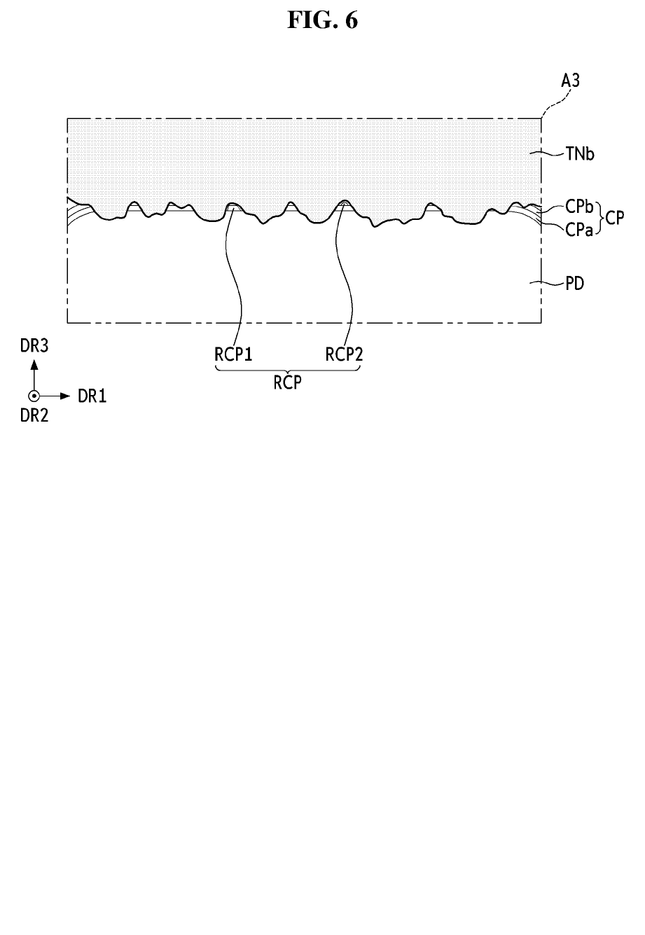

FIG. 6 is an enlarged view of portion A3 of FIG. 5.

Referring to FIG. 6, the surface of the second terminal electrode TNb facing the pad PD of the display panel DSP may have an irregular uneven shape. The uneven shape of the second terminal electrode TNb may be formed by being melted and solidified during the process of attaching the display panel DSP with the driver circuit DDC, as will be described later. The process of forming the uneven surface of the second terminal electrode TNb will be described below with reference to FIGS. 7 and 8. The second terminal electrode TNb may have “elevations” in the reverse direction of the third direction DR3 and “depressions” in the third direction DR3. The depressions in the third direction DR3 may be in direct contact with the residual capping pattern RCP. The second terminal electrode TNb protruding in the reverse direction of the third direction DR3 may be in direct contact with the pad PD of the display panel DSP with a large contact area. By this contact, the contact resistance between the pad PD of the display panel DSP and the terminal TN of the driver circuit DDC can be reduced, and the reliability of the display device 10 can be improved.

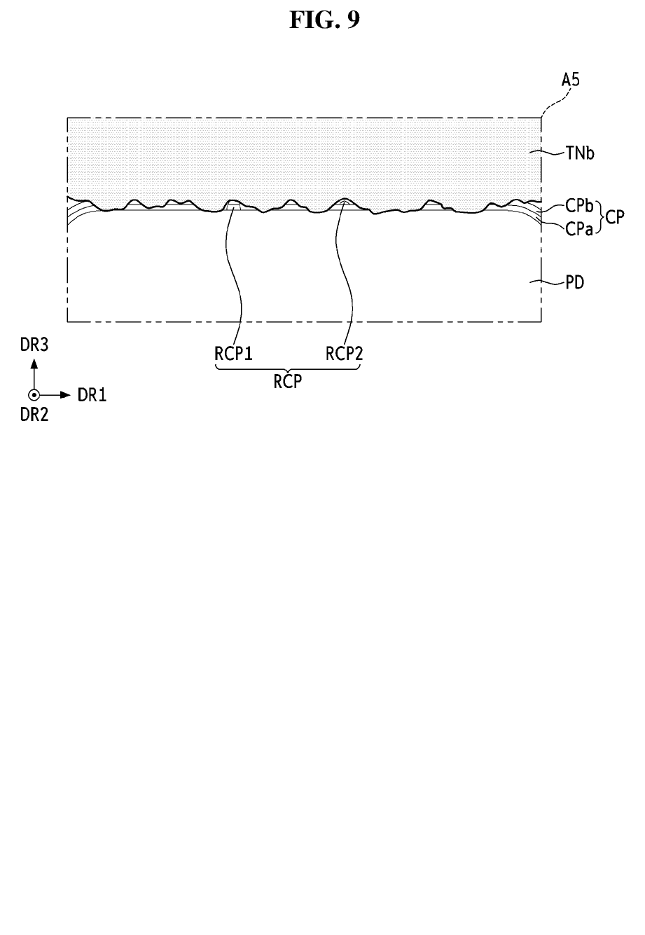

FIGS. 7 and 8 are views for illustrating a process of attaching a display panel to a driver circuit according to an embodiment. FIG. 9 is an enlarged view of portion A5 of FIG. 8.

Referring to FIGS. 7, 8, and 9, the display panel DSP and the driver circuit DDC may be attached to each other via a thermal compression bonding process. At the beginning of the thermal compression bonding process, the terminal TN of the driver circuit DDC may be placed such that it overlaps the pad PD of the display panel DSP in the third direction DR3, and may be compressed. During the compression process, the second terminal electrode TNb of the terminal TN may be in line contact with the capping member CP located on the pad PD. As shown in FIG. 9, the surface of the second terminal electrode TNb which faces the pad PD of the display panel DSP may have fine irregular uneven shape. For example, the second terminal electrode TNb may have fine elevations in the reverse direction of the third direction DR3 (i.e., downward in reference to FIG. 9) and fine depressions in the third direction DR3. The portion of the second terminal electrode TNb that is protruding in the reverse direction of the third direction DR3 may penetrate the capping member CP during the compression process and may come in direct physical contact with the pad PD.

Subsequently, the capping member CP is damaged by the pressure applied by the second terminal electrode TNb, so that residual capping patterns RCP may be formed. The pad PD may be exposed between the residual capping patterns RCP, so that the second terminal electrode TNb may physically come into direct contact with the pad PD. However, the physical contact between the second terminal electrode TNb of the driver circuit DDC and the pad PD of the display panel DSP has a small contact area and may be unstable if maintained only by the pressurization process. A more stable physical contact between the second terminal electrode Nb and the pad PD may be achieved by adjusting or increasing the contact resistance.

In the latter stage of the thermal compression bonding process, heat may be transferred to the second terminal electrode TNb to melt the second terminal electrode TNb. The molten second terminal electrode TNb may flow or move fluidly between the residual capping patterns RCP and may further increase the contact area with the pad PD. In addition, the molten second terminal electrode TNb may be solidified into an irregular uneven shape while having an increased contact area with the pad PD, so that the second terminal electrode TNb may form strong bonding with the pad PD. Accordingly, the contact resistance between the pad PD of the display panel DSP and the terminal TN of the driver circuit DDC can be reduced, and the reliability of the display device 10 can be improved.

Through this heat-compression bonding process, the display device 10 in which the display panel DSP and the driver circuit DDC bonded together as shown in FIGS. 5 and 6 can be formed.

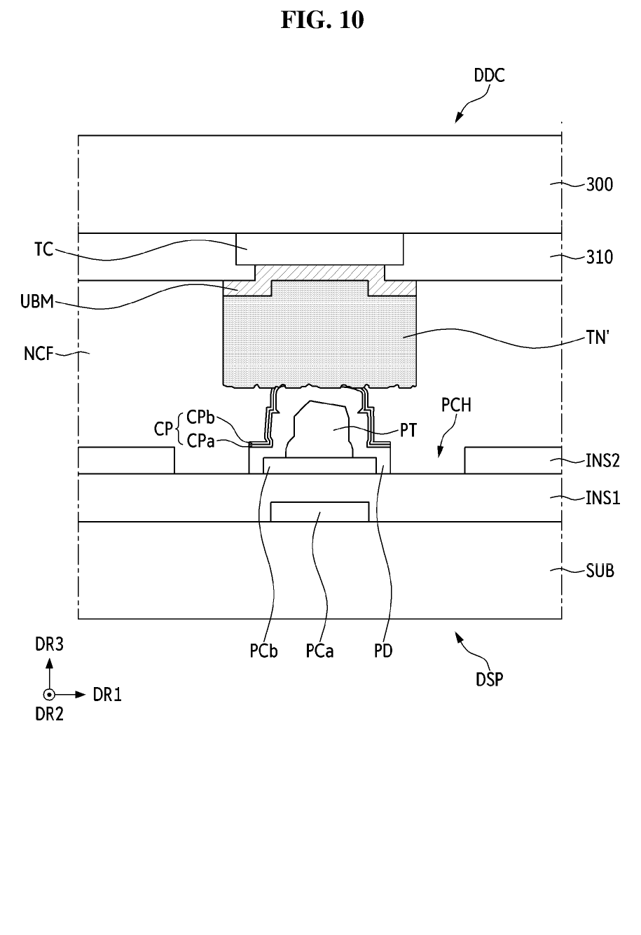

FIG. 10 is a cross-sectional view of a display device according to another embodiment of the present disclosure, taken along line X1 – X1' of FIG. 3.

The following descriptions will focus on differences, and the redundant descriptions will be omitted.

The embodiment of FIG. 10 is different from the embodiment of FIG. 5 in that a terminal TN' of a driver circuit DDC may be made up of a single layer. The terminal TN' may include a high-hardness, heat-melting metal (solder metal). The surface of the terminal TN' which faces the pad PD of the display panel DSP may have irregular uneven shape.

There may be a residual capping pattern RCP on the surface of the pad PD of the display panel DSP which faces the terminal TN' of the driver circuit DDC. The residual capping pattern RCP may be a remaining portion of the capping member CP that is pressed and damaged by the high hardness terminal TN' during the process of attaching the display panel DSP with the driver circuit DDC. The residual capping pattern RCP may include a first residual capping pattern RCP1 and a second residual capping pattern RCP2. The first residual capping pattern RCP1 may be a remaining portion of the first capping member CPa. The first residual capping pattern RCP1 may be located on the pad PD. In some embodiments, the first residual capping pattern RCP1 may be in direct contact with the terminal TN'. Alternatively, in some embodiments, the first residual capping pattern RCP1 may not be in direct contact with the terminal TN'. The second residual capping pattern RCP2 may be a remaining portion of the second capping member CPb. The second residual capping pattern RCP2 may be located on the first residual capping pattern RCP1. In some embodiments, the second residual capping pattern RCP2 may be in direct contact with the terminal TN'. In some embodiments, the second residual capping pattern RCP2 may not be in direct contact with the terminal TN'.

A non-conductive film (NCF) may be placed between the display panel DSP and the driver circuit DDC. For example, the non-conductive film NCF may be located between the pad PD and the terminal TN'. The display panel DSP and the driver circuit DDC may be attached to each other by the non-conductive film NCF. The non-conductive film NCF may be made of a material including a thermosetting resin. The melting point of the non-conductive film NCF may be different from the melting point of the terminal TN'. In some embodiments, the melting point of the terminal TN' may be lower than the melting point of the non-conductive film NCF. Therefore, in the process of bonding the display panel DSP with the driver circuit DDC with the non-conductive film NCF, the connection between the pad PD of the display panel DSP and the terminal TN of the driver circuit DDC can be made without requiring additional heat to melt the terminal TN'.

The display device according to the embodiment may be applied to a variety of electronic devices. An electronic device according to an embodiment includes the display device described above, and may further include a module or device having additional features in addition to the display device.

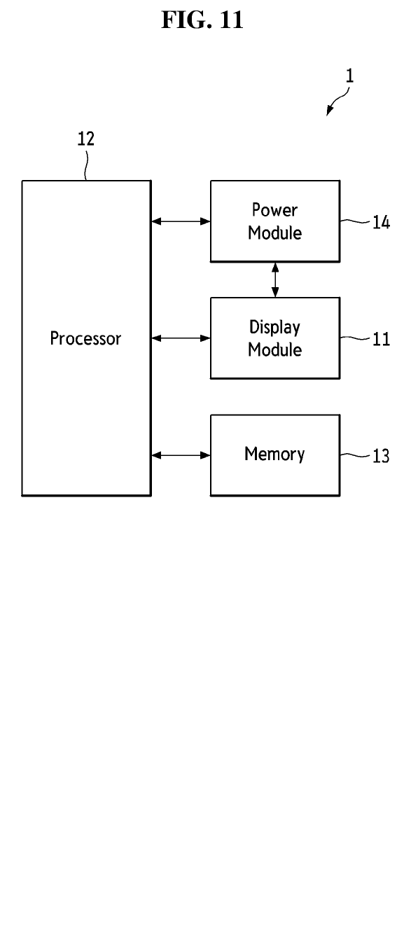

FIG. 11 is a block diagram of an electronic device according to an embodiment of the present disclosure.

Referring to FIG. 11, an electronic device 1 according to an embodiment of the present disclosure may include a display module 11, a processor 12, a memory 13, and a power module 14.

The processor 12 may include at least one of: a central processing unit (CPU), an application processor (AP), a graphic processing unit (GPU), a communication processor (CP), an image signal processor (ISP), and a controller.

The memory 13 may store data information required for the operation of the processor 12 or the display module 11. When the processor 12 executes an application stored in the memory 13, an image data signal and/or an input control signal may be transmitted to the display module 11. The display module 11 may process the received signal and output image information through a display screen.

The power module 14 may include a power supply module such as a power adapter and a battery device, and a power conversion module that converts the power supplied by the power supply module to generate power required for the operation of the electronic device 1.

At least one of the elements of the electronic device 1 described above may be included in the display devices according to the embodiments described above. In addition, some of the individual modules functioning as a single module may be included in the display device while some others may be provided separately from the display device. For example, the display device may include the display module 11, and the processor 12, the memory 13 and the power module 14 may be implemented as other devices inside the electronic device 1 instead of the display device.

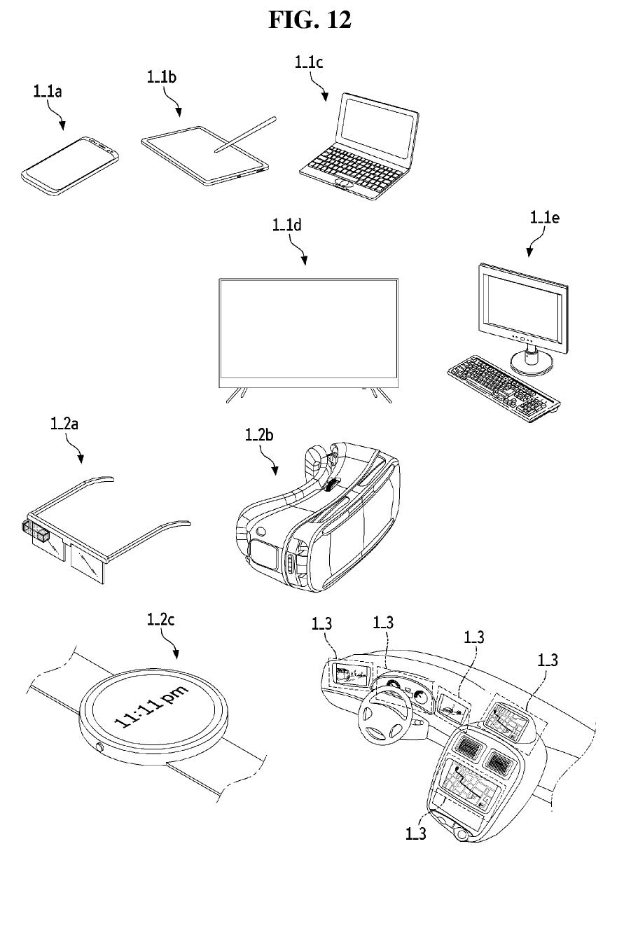

FIG. 12 is a view showing electronic devices according to a variety of embodiments of the present disclosure.

Referring to FIG. 12, a variety of electronic devices employing display devices according to embodiments may include not only image display electronic devices such as a smart phone 1_1a, a tablet PC 1_1b, a laptop computer 1_1c, a TV 1_1d and a desktop monitor 1_1e, but also wearable electronic devices including display modules such as smart glasses 1_2a, a head-mounted display 1_2b and a smart watch 1_2c, and electronic devices for vehicles 1_3 including display modules such as a center information display (CID) placed on the dashboard, the center fascia and the dashboard of a vehicle, and a room mirror display.

Those skilled in the art will appreciate that many variations and modifications can be made to the embodiments that are presented without substantially departing from the principles of the present invention. Therefore, the disclosed embodiments of the invention are used in a generic and descriptive sense only and not for purposes of limitation.

What is claimed is:

1. A display device comprising:
a display panel that comprises:
a first substrate;
a pad located on the first substrate; and
a residual capping pattern located on the pad; and
a driver circuit connected to the display panel, wherein the driver circuit comprises:
a second substrate; and
a terminal located on the second substrate and directly connected to the pad of the display panel,
and
wherein the residual capping pattern is located between the pad of the display panel and the terminal of the driver circuit.

2. The display device of claim 1, wherein the terminal of the driver circuit comprises a first terminal electrode located on the second substrate, and a second terminal electrode located on the first terminal electrode, and
wherein a hardness of the first terminal electrode is different from a hardness of the second terminal electrode.

3. The display device of claim 2, wherein a hardness of the second terminal electrode is greater than a hardness of the first terminal electrode.

4. The display device of claim 1, wherein the terminal of the driver circuit comprises: a first terminal electrode located on the second substrate, and a second terminal electrode located on the first terminal electrode, and
wherein the second terminal electrode is in direct contact with the pad of the display panel.

5. The display device of claim 4, wherein the residual capping pattern comprises a first residual capping pattern located on the pad, and a second residual capping pattern located on the first residual capping pattern,
wherein the first residual capping pattern is not in direct contact with the second terminal electrode of the driver circuit, and
wherein the second residual capping pattern is in direct contact with the second terminal electrode of the driver circuit.

6. The display device of claim 4, wherein the residual capping pattern comprises:
a first residual capping pattern located on the pad, and
a second residual capping pattern located on the first residual capping pattern,
wherein the first residual capping pattern is in direct contact with the second terminal electrode of the driver circuit, and
wherein the second residual capping pattern is not in direct contact with the second terminal electrode of the driver circuit.

7. The display device of claim 4, wherein the residual capping pattern comprises a first residual capping pattern located on the pad, and a second residual capping pattern located on the first residual capping pattern, and
wherein the first residual capping pattern and the second residual capping pattern are in direct contact with the second terminal electrode of the driver circuit.

8. The display device of claim 1, wherein the terminal of the driver circuit comprises: a first terminal electrode located on the second substrate, and a second terminal electrode located on the first terminal electrode, and
wherein the second terminal electrode comprises a solder metal.

9. The display device of claim 8, further comprising:
a non-conductive film between the display panel and the driver circuit,
wherein a melting point of the second terminal electrode is different from a melting point of the non-conductive film.

10. The display device of claim 9, wherein the melting point of the second terminal electrode is lower than the melting point of the non-conductive film.

11. The display device of claim 8, wherein a surface of the second terminal electrode facing the pad has an irregular uneven shape.

12. The display device of claim 1, wherein the display panel further comprises a capping member located on the pad, and
wherein the terminal of the driver circuit extends through the capping member and is in direct contact with the pad.

13. The display device of claim 1, wherein the residual capping pattern comprises a first residual capping pattern located on the pad, and a second residual capping pattern located on the first residual capping pattern,
wherein the first residual capping pattern is not in direct contact with the terminal of the driver circuit, and
wherein the second residual capping pattern is in direct contact with the terminal of the driver circuit.

14. The display device of claim 1, wherein the residual capping pattern comprises a first residual capping pattern located on the pad, and a second residual capping pattern located on the first residual capping pattern,
wherein the first residual capping pattern is in direct contact with the terminal of the driver circuit, and
wherein the second residual capping pattern is not in direct contact with the terminal of the driver circuit.

15. The display device of claim 1, wherein the residual capping pattern comprises a first residual capping pattern located on the pad and a second residual capping pattern located on the first residual capping pattern, and
wherein the first residual capping pattern and the second residual capping pattern are in direct contact with the terminal of the driver circuit.

16. The display device of claim 1, wherein the terminal comprises a solder metal.

17. The display device of claim 16, further comprising:
a non-conductive film between the display panel and the driver circuit,
wherein a melting point of the terminal is different from a melting point of the non-conductive film.

18. The display device of claim 17, wherein the melting point of the terminal is lower than the melting point of the non-conductive film.

19. The display device of claim 16, wherein a surface of the terminal facing the pad has an irregular uneven shape.

20. An electronic device comprising:
a display device for displaying an image; and
a processor for transmitting an image data signal for displaying the image to the display device,
wherein the display device comprises:
a display panel; and
a driver circuit that is connected to the display panel,
wherein the display panel comprises:
a first substrate;
a pad located on the first substrate; and
a residual capping pattern located on the pad; and
the driver circuit comprises:
a second substrate; and
a terminal located on the second substrate and directly connected to the pad of the display panel,
and
wherein the residual capping pattern is located between the pad of the display panel and the terminal of the driver circuit.
